(19) United States
(12) Patent Application Publication
(10) Pub. No.: US 2024/0322593 A1
(43) Pub. Date: Sep. 26, 2024

(54) SOLAR CHARGING SYSTEM

(71) Applicant: TOYOTA JIDOSHA KABUSHIKI KAISHA, Toyota-shi, Aichi-ken (JP)

(72) Inventor: Takuya YASUI, Toyota-shi (JP)

(73) Assignee: TOYOTA JIDOSHA KABUSHIKI KAISHA, Toyota-shi, Aichi-ken (JP)

(21) Appl. No.: 18/591,827

(22) Filed: Feb. 29, 2024

(30) Foreign Application Priority Data
Mar. 23, 2023 (JP) 2023-046479

(51) Int. Cl. H02J 7/35; H02J 3/38; H02M 1/00; H10K 30/57

(52) U.S. Cl. CPC H02J 7/35; H02J 3/38; H02M 1/0009; H10K 30/57; H02J 2207/20; H02J 2300/26

(57) ABSTRACT

A solar charging system includes a solar panel including a tandem solar cell. A control unit includes a measuring circuit that measures a voltage and a current of power input to the first DC-DC converter. A storage device stores data defining a relationship between a first command value and a second command value. The solar charging system controls the first DC-DC converter according to the first command value and controls the second DC-DC converter according to the second command value. The first command value is determined by executing maximum power point tracking while measuring a voltage and a current. The second command value is determined by using the data stored in the storage device and based on the first command value.

### BACKGROUND

### 1. Field

The present disclosure relates to a solar charging system.

### 2. Description of Related Art

Japanese Patent No. 7180295 discloses a solar charging system. The solar charging system includes a solar panel, a battery, and a control unit. The battery temporarily stores power generated by the solar panel. The control unit controls charging of the battery by the solar cell panel.

Development is underway on tandem solar cells, which include multiple solar cells stacked together, each utilizing different wavelength regions for power generation. In a tandem solar cell, power is generated by each of the stacked solar cells. Therefore, a tandem-type solar cell enhances the power generation efficiency per unit area.

The control unit of a solar charging system performs maximum power point tracking (MPPT) to extract the maximum power from solar panels. The power generation amount of a solar panel changes depending on the combination of a voltage and a current when power is extracted from the solar panel. In the maximum power point tracking, the control unit gradually adjusts the voltage in the direction of increasing power by controlling a DC-DC converter while measuring current and voltage. In this manner, the control unit searches for the combination of voltage and current that maximizes the power extracted from the solar panel through the maximum power point tracking. By executing the maximum power point tracking, the control unit continues to control the DC-DC converter so as to achieve the optimum operating point, which is the combination of the voltage and the current that maximizes the power.

In a solar charging system equipped with a solar panel including a tandem solar cell, when performing the maximum power point tracking, it is necessary to provide separate measuring circuits for each stacked layer of solar cells to obtain voltage and current. Additionally, when performing the maximum power point tracking for each layer of a tandem solar cell, the control unit needs to search for the optimal operating point for each layer.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a solar charging system includes a solar panel, a battery, and a control unit. The solar panel includes a tandem solar cell in which a first solar cell and a second solar cell are stacked. The first solar cell and the second collar cell use different wavelength regions to generate power. The battery that is charged with the power generated by the solar panel. The control unit includes a first DC-DC converter that converts power generated by the first solar cell and charges the battery with the converted power, a measuring circuit that measures a voltage and a current of power input to the first DC-DC converter, a second DC-DC converter that converts power generated by the second solar cell and charges the battery with the converted power, and a controller that controls the first DC-DC converter and the second DC-DC converter. The controller includes processing circuitry. The processing circuitry includes a storage device that stores data defining a relationship between a first command value for the first DC-DC converter and a second command value for the second DC-DC converter, and a processing device. The solar charging system is configured to charge the battery with the power generated by the solar panel by controlling the first DC-DC converter according to the first command value and controlling the second DC-DC converter according to the second command value. The first command value is determined by the processing device controlling the first DC-DC converter to execute maximum power point tracking while measuring a voltage and a current with the measuring circuit. The second command value is determined by the processing device using the data stored in the storage device and based on the first command value.

Other features and aspects will be apparent from the following detailed description, the drawings, and the claims.

### BRIEF DESCRIPTION OF THE DRAWINGS

FIG. 1 is a schematic diagram showing a configuration of a solar charging system according to one embodiment.

FIG. 2 is a graph showing an example of a relationship between power and voltage in a solar cell.

FIG. 3 is a table for explaining an example of table data stored in a storage device of the solar charging system according to the embodiment.

FIG. 4 is a schematic diagram showing a configuration of a test system used for creating the table data.

FIG. 5 is a flowchart showing the flow of processes executed by the processing device of the solar charging system according to the embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, except for operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

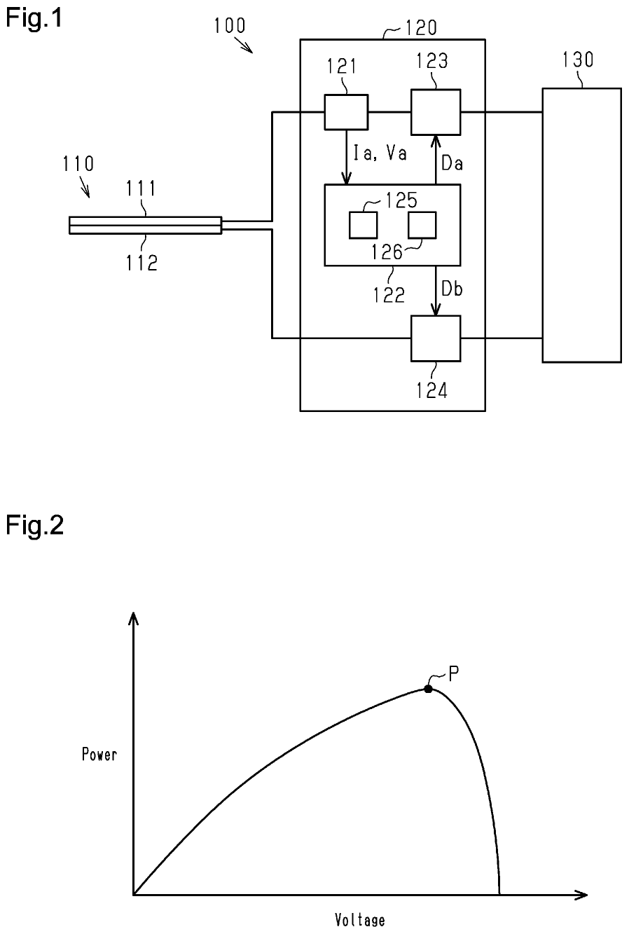

Hereinafter, an embodiment of a solar charging system will be described with reference to FIGS. 1 to 5.

### Configuration of Solar Charging System 100

As shown in FIG. 1, the solar charging system 100 includes a solar panel 110, a control unit 120, and a battery 130. The solar charging system 100 is mounted on a vehicle, for example, and charges a battery 130 with electricity generated by a solar panel 110.

### Configuration of Solar Panel 110

The solar panel 110 is installed on the roof of the vehicle, for example. The solar panel 110 may be installed on a hood of the vehicle. The solar panel 110 is formed by arranging and unitizing a plurality of tandem solar cells. The tandem solar cell is configured by stacking a plurality of solar cells having different wavelength regions used for power generation. The solar panel 110 is configured by a tandem solar cell in which a first solar cell 111 and a second solar cell 112 are overlapped. As shown in FIG. 1, the tandem solar cell has a structure in which a first solar cell 111 is superposed on a second solar cell 112. The solar panel 110 is installed in a direction in which the first solar cell 111 of the first solar cell 111 and the second solar cell 112 of the tandem solar cells is positioned on the front surface side. That is, the tandem solar cell is composed of the first solar cell 111 in the top layer and the second solar cell 112 in the bottom layer.

The first solar cell 111 is, for example, a perovskite solar cell. Perovskite solar cells can be made by coating and printing materials and are characterized by being thin and resistant to distortion. Therefore, the perovskite solar cell is suitable for a transmission type solar cell that transmits light. The second solar cell 112 is, for example, a silicon solar cell. The silicon type solar cell is a solar cell capable of obtaining stable power generation efficiency and high output. In the case of the solar panel 110, the amount of power generated by the first solar cell 111 is less than the amount of power generated by the second solar cell 112. The solar cells of each layer in the tandem solar cell may be other types of solar cells. The tandem solar cell is configured such that light transmitted through the top layer can be utilized for power generation in the bottom layer.

The battery 130 is charged with electricity generated by the solar panel 110. The battery 130 is, for example, a nickel-hydrogen battery. The battery 130 is not limited to a nickel-hydrogen battery and may be another type of battery.

### Configuration of Control Unit 120

As shown in FIG. 1, the solar panel 110 is connected to the control unit 120. A battery 130 is also connected to the control unit 120. The control unit 120 includes a first DC-DC converter 123, a second DC-DC converter 124, a measuring circuit 121, and a controller 122. The first DC-DC converter 123 converts electric power generated by the first solar cell 111 and charges the battery 130 with the converted electric power. The second DC-DC converter 124 converts electric power generated by the second solar cell 112 and charges the battery 130 with the converted electric power. The controller 122 controls the first DC-DC converter 123 and the second DC-DC converter 124. The controller 122 includes a processing device 125 and a storage device 126. The processing device 125 executes a program to control the first DC-DC converter 123 and the second DC-DC converter 124.

The first solar cell 111 is connected to the first DC-DC converter 123. A measuring circuit 121 is provided in the middle of a circuit connecting the first solar cell 111 and the first DC-DC converter 123. The measuring circuit 121 measures the voltage Va and the current Ia input to the first DC-DC converter 123. Information on the voltage Va and the current Ia measured by the measuring circuit 121 is input to the controller 122. The controller 122 controls the first DC-DC converter 123 and the second DC-DC converter 124 based on the information of the voltage Va and the current Ia measured by the measuring circuit 121.

### Maximum Power Point Tracking

Generally, the control unit of the solar charging system performs maximum power point tracking to draw maximum power from the solar panel. The power generation amount of a solar panel changes depending on the combination of a voltage and a current when power is extracted from the solar panel. In the maximum power point tracking, the control unit gradually adjusts the voltage in the direction of increasing power by controlling a DC-DC converter while measuring current and voltage.

FIG. 2 shows an example of the relationship between power and voltage in a solar cell. The control unit gradually changes the voltage in a direction in which the power increases in the maximum power point tracking using such a relationship between the power and the voltage. When the power changes from increase to decrease, the control unit sets a combination of the voltage at the point P at which the power changes from increase to decrease and the current at that time as the optimum operating point. The control unit then controls the DC-DC converter to achieve an optimum operating point to draw maximum power from the solar panel. After the power changes from increasing to decreasing, the control unit changes the voltage in a direction to increase the power by reversing the direction of changing the voltage. The relationship between power and voltage in a solar cell varies with the amount of solar radiation. That is, the optimum operating point varies depending on the amount of solar radiation. Therefore, in the maximum power point tracking, the control unit repeats this series of operations to continuously control the DC-DC converter while searching for the optimum operating point so that the power is always maximized.

In a solar charging system 100 provided with a tandem solar cell, a control unit 120 controls a first DC-DC converter 123 and a second DC-DC converter 124 to realize maximum power point tracking.

The storage device 126 of the controller 122 stores data defining the relationship between the first command value Da for the first DC-DC converter 123 and the second command value Db for the second DC-DC converter 124.

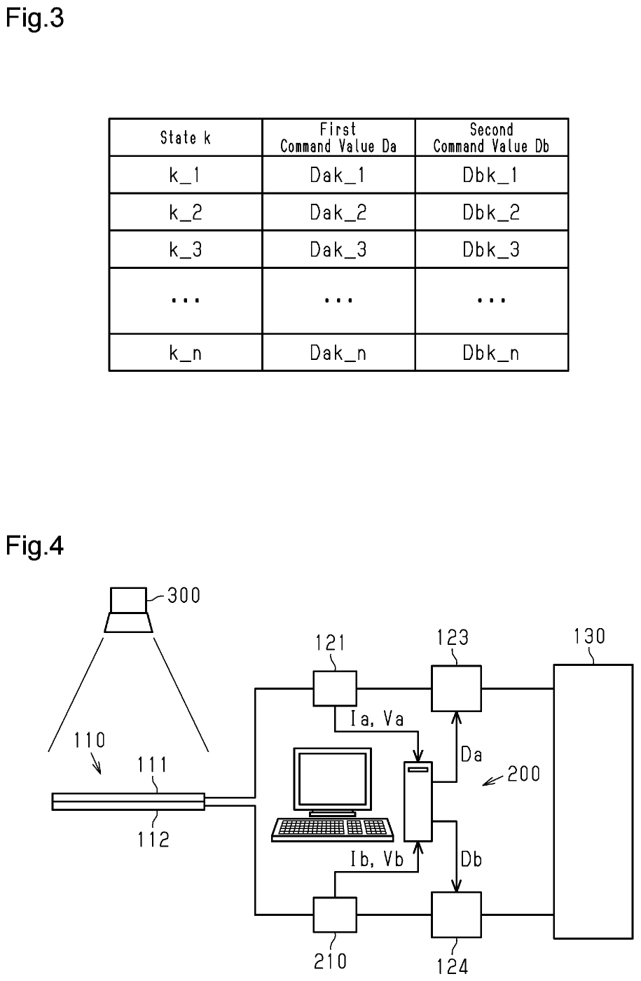

For example, as illustrated in FIG. 3, the data stored in the storage device 126 is table data in which the first command value Da and the second command value Db are recorded in association with each other for each of a plurality of different states k. In FIG. 3, a plurality of different states k are distinguished from each other by a number following “_”. The first command value Da and the second command value Db in each state k are denoted by a symbol indicating each state k. For example, the first command value Dak_1 and the second command value Dbk_1 are the first command value Da and the second command value Db in the state k_1. The first command value Da in FIG. 3 is a first command value Da for realizing an optimum operating point in the first solar cell 111. The second command value Db in FIG. 3 is a second command value Db for realizing the optimum operating point in the second solar cell 112. The table data is created through a test performed in advance.

### Creation of Table Data

FIG. 4 is a schematic diagram showing a configuration of a test system for performing a test for creating table data. This test system is a system in which the controller 122 in the control unit 120 of the solar charging system 100 is replaced with a computer 200. In this test system, a measuring circuit 210 is provided in the middle of a circuit connecting the second solar cell 112 and the second DC-DC converter 124. The measuring circuit 210 measures the voltage Vb and the current Ib input to the second DC-DC converter 124. Information on the voltage Vb and the current Ib measured by the measuring circuit 210 is input to the computer 200. The computer 200 controls the first DC-DC converter 123 based on information on the voltage Va and the current Ia measured by the measuring circuit 121. The computer 200 controls the second DC-DC converter 124 based on information on the voltage Vb and the current Ib measured by the measuring circuit 210.

Further, the test system includes a lighting device 300 that irradiates the solar panel 110 with light simulating sunlight. The test system performs tests simulating various solar radiation states by controlling the lighting device 300. Specifically, computer 200 executes the maximum power point tracking for first solar cell 111 and the maximum power point tracking for second solar cell 112. The computer 200 performs maximum power point tracking for the first solar cell 111 based on information of the voltage Va and the current Ia measured by the measuring circuit 121. The computer 200 performs maximum power point tracking for the second solar cell 112 based on the information of the voltage Vb and the current Ib measured by the measuring circuit 210. Then, the computer 200 stores a set of the first command value Da and the second command value Db for realizing the optimum operating point in the same state k. Such a test is repeatedly performed while changing the amount of solar radiation. Thus, the first command value Da for realizing the optimum operating point and the second command value Db for realizing the optimum operating point can be associated with each other and recorded in the computer 200 for each of the plurality of states k. The table data shown in FIG. 3 is created based on data stored in the computer 200.

Table data created based on data collected through such a test is stored in the storage device 126 of the controller 122.

Routines executed by the control unit 120

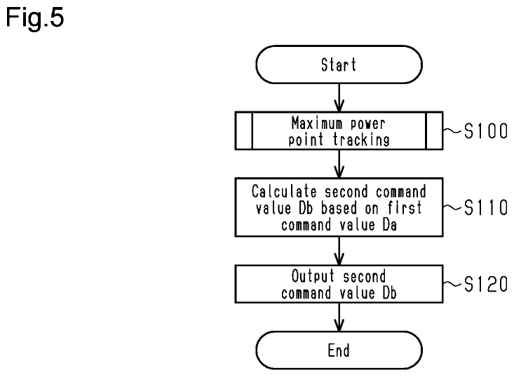

Next, a flow of processing in a routine executed by the control unit 120 of the solar charging system 100 will be described with reference to FIG. 5. The routine shown in FIG. 5 is repeatedly executed by the processing device 125 of the controller 122 during operation of the solar charging system 100.

As shown in FIG. 5, when this routine is started, first, in the process of step S100, the processing device 125 executes the maximum power point tracking for the first solar cell 111. As described above, in the solar charging system 100, the processing device 125 executes the maximum power point tracking based on the voltage Va and the current Ia measured by using the measuring circuit 121. The processing device 125 determines the first command value Da so as to achieve the optimum operating point. Then, the processing device 125 outputs the first command value Da to the first DC-DC converter 123. This causes the first solar cell 111 to operate at the optimum operating point.

Next, in the process of step S110, the processing device 125 calculates the second command value Db based on the first command value Da. At this time, the processing device 125 calculates the second command value Db corresponding to the first command value Da with reference to the table data stored in the storage device 126.

Next, in the process of step S120, the processing device 125 outputs the second command value Db to the second DC-DC converter 124. As a result, the second solar cell 112 also operates at the optimum operating point.

After executing the process of step S120, the processing device 125 temporarily suspends the current routine.

### Operation of Present Embodiment

The controller 122 measures the voltage Va and the current Ia input to the first DC-DC converter 123 using the measuring circuit 121. The controller 122 executes the maximum power point tracking based on the measured voltage Va and current Ia to determine the first command value Da so as to achieve the optimum operating point. Then, the controller 122 determines the second command value Db based on the first command value Da using the data stored in the storage device 126. The solar charging system 100 can determine the second command value Db without performing the maximum power point tracking for the second solar cell 112.

### Advantages of Present Embodiment

(1) The solar charging system 100 does not need a measuring circuit that measures the voltage Vb and the current Ib of the electric power input to the second DC-DC converter 124, and can efficiently extract electric power from the solar panel 110 configured by a tandem solar cell.
(2) Table data is stored in the storage device 126 as data defining the relationship between the first command value Da and the second command value Db. Therefore, the solar charging system 100 can calculate the second command value Db based on the first command value Da with reference to the table data.
(3) In the solar charging system 100, the power generation amount in the first solar cell 111 is smaller than the power generation amount in the second solar cell 112.

When the maximum power point tracking is executed in a solar cell having a large amount of power generation, the amount of change in power when the voltage is changed is larger than when the maximum power point tracking is executed in a solar cell having a small amount of power generation. Therefore, when the maximum power point tracking is executed in the solar cell having a large power generation amount, the drop of the power in the case where the power is lowered by changing the voltage becomes larger than that in the case where the maximum power point tracking is executed in the solar cell having a small power generation amount.

The solar charging system 100 performs maximum power point tracking on the first solar cell 111. The power generation amount of the first solar cell 111 is smaller than the power generation amount of the second solar cell 112. Therefore, the solar charging system 100 can suppress the drop of the electric power when the electric power is reduced by changing the voltage Va in accordance with the maximum power point tracking as compared with the configuration in which the maximum power point tracking is performed in the second solar cell 112.
(4) A perovskite solar cell can be made thinner than a silicon solar cell. Therefore, the perovskite solar cell can easily realize a transmission type solar cell that transmits light. In the solar panel 110, the first solar cell 111 which is the top layer is a perovskite solar cell. A first solar cell 111 made of a perovskite solar cell is superposed on a second solar cell 112 made of a silicon solar cell. In the solar panel 110, the silicon type solar cell of the bottom layer generates power by light transmitted through the top layer. Therefore, the solar panel 110 can efficiently generate power.

### Modifications

The above-described embodiment may be modified as follows. The above-described embodiment and the following modifications can be combined as long as the combined modifications remain technically consistent with each other.

The solar panel 110 includes a two layer tandem solar cell including a first solar cell 111 and a second solar cell 112. On the other hand, the same configuration can be applied to a solar charging system including a solar panel including three or more layers of tandem solar cells. The maximum power point tracking is performed for any layer of the tandem solar cell, and based on the command value for the solar cell for which the maximum power point tracking has been performed using the data stored in the storage device 126, the command values for the solar cells of other layers can be calculated.

Among the plurality of solar cells constituting the tandem solar cell, which solar cell is to be subjected to the maximum power point tracking can be appropriately changed and designed. The maximum power point tracking may be executed in a solar cell that generates a larger amount of power than other solar cells. When the power generation amounts in the respective layers of the tandem solar cell are substantially equal to each other, the maximum power point tracking may be executed in a layer having an electrical characteristic in which the current at the optimum operating point is small. As the current flowing through the measuring circuit increases, the heat generation in the shunt resistor for measuring the voltage increases. Therefore, when the maximum power point tracking is performed in a layer having an electrical characteristic in which a current is large, energy loss due to heat generation in the measuring circuit increases. If the maximum power point tracking is executed in a layer having an electrical characteristic in which the current at the optimum operating point is small, the energy loss can be suppressed.

The solar charging system 100 calculates the second command value Db based on the first command value Da using the table data stored in the storage device 126. On the other hand, data stored in the storage device 126 is not limited to table data. The data stored in the storage device 126 may be any data as long as the second command value Db can be calculated based on the first command value Da. For example, a mathematical expression or a model indicating the relationship between the first command value Da and the second command value Db may be derived based on data recorded in the computer 200, and data of the mathematical expression or the model may be stored in the storage device 126.

The controller 122 is not limited to a device that includes the processing device 125 and the storage device 126 and executes software processing. For example, at least part of the processes executed by the software in the above-described embodiment may be executed by hardware circuits dedicated to executing these processes (such as an application-specific integrated circuit (ASIC)). That is, the controller 122 may have any one of the following configurations (a) to (a) Processing circuitry that executes all of the above-described processes in accordance with a program, and a program storage device such as a ROM that stores the program. (b) Processing circuitry and a program storage device for executing a part of the processing in accordance with a program, and a dedicated hardware circuit for executing the remaining processing. (c) A configuration including a dedicated hardware circuit that executes all of the above-described processes. Multiple software processing devices each including processing circuitry and a program storage device and multiple dedicated hardware circuits may be provided.

What is claimed is:

1. A solar charging system, comprising:
a solar panel that includes a tandem solar cell in which a first solar cell and a second solar cell are stacked, the first solar cell and the second collar cell using different wavelength regions to generate power;
a battery that is charged with the power generated by the solar panel; and
a control unit, wherein
the control unit includes:
a first DC-DC converter that converts power generated by the first solar cell and charges the battery with the converted power;
a measuring circuit that measures a voltage and a current of power input to the first DC-DC converter;
a second DC-DC converter that converts power generated by the second solar cell and charges the battery with the converted power; and
a controller that controls the first DC-DC converter and the second DC-DC converter,
the controller includes processing circuitry,
the processing circuitry includes:
a storage device that stores data defining a relationship between a first command value for the first DC-DC converter and a second command value for the second DC-DC converter; and
a processing device,
the solar charging system is configured to charge the battery with the power generated by the solar panel by controlling the first DC-DC converter according to the first command value and controlling the second DC-DC converter according to the second command value,
the first command value is determined by the processing device controlling the first DC-DC converter to execute maximum power point tracking while measuring a voltage and a current with the measuring circuit, and
the second command value is determined by the processing device using the data stored in the storage device and based on the first command value.

2. The solar charging system according to claim 1, wherein
table data is stored as the data in the storage device, and
the table data is recorded by correlating, for each of multiple different insolation conditions, the first command value that achieves an optimal operating point in the first solar cell and the second command value that achieves an optimal operating point in the second solar cell.

3. The solar charging system according to claim 1, wherein a power generation amount in the first solar cell is less than a power generation amount in the second solar cell.

4. The solar charging system according to claim 1, wherein the solar panel is formed by the tandem solar cell having a structure in which the first solar cell is stacked as a top layer on the second solar cell.

5. The solar charging system according to claim 4, wherein
the first solar cell is a perovskite solar cell, and
the second solar cell is a silicon solar cell.
